(19) United States
(12) Patent Application Publication
(10) Pub. No.: US 2010/0248448 A1
(43) Pub. Date: Sep. 30, 2010

(54) METHOD OF MANUFACTURING SEMICONDUCTOR DEVICES

(75) Inventors: Hitoshi Nakamura, Tokyo (JP); Masato Negishi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/719,939

(22) Filed: Mar. 9, 2010

(30) Foreign Application Priority Data
Mar. 25, 2009 (JP) 2009-073206

(51) Int. Cl. H01L 21/78

(52) U.S. Cl. 438/460; 257/E21.599

(57) ABSTRACT

A method of manufacturing semiconductor devices by cleaving a semiconductor wafer along a crystal orientation of the semiconductor wafer includes forming a semiconductor layer on the semiconductor wafer, forming an insulating film on the semiconductor layer such that the insulating film includes an insulating film thinned region extending parallel to the crystal orientation and that is thinner than other regions of the insulating film, forming an electrode on the insulating film and that crosses the insulating film thinned region, forming a cut in the insulating film thinned region, the cut serving as a starting point for cleaving, and cleaving the semiconductor wafer such that cleaving starts at the cut and propagates along the insulating film thinned region.

### BACKGROUND OF THE INVENTION

1. Field of the Invention

The present invention relates to a method of manufacturing a plurality of semiconductor devices by cleaving a semiconductor wafer into multiple pieces.

2. Background Art

There is a practice of first forming a plurality of semiconductor devices on a single semiconductor wafer and then splitting the wafer into the individual devices by utilizing the “cleavability” of the semiconductor wafer. The term “cleavability” of a semiconductor wafer refers to the fact that the semiconductor wafer can be cleaved along crystal planes with ease. Splitting a semiconductor wafer by utilizing its “cleavability” (hereinafter referred to simply as “cleaving”) results in the formation of exposed faces which are generally characterized by being flat and uniform, as compared with those formed by dicing.

Such cleaving is a technique used to manufacture semiconductor light emitting devices of the type that emit light from an end face thereof. That is, in the manufacture of these semiconductor light emitting devices, light emitting end faces that are flat and uniform are formed and exposed by cleaving, and a multilayer film of a dielectric material, etc. is formed on these end faces to improve the characteristics and reliability of the semiconductor light emitting devices. More specifically, a uniform multilayer film can be formed on the light emitting end faces if they are flat and uniform, resulting in reduced variation in the light emitting direction.

It will be noted that the formation of flat and uniform end faces by cleaving, as described above, not only enhances the characteristics and reliability of the semiconductor light emitting devices, but also leads to the formation of a straight cleavage line, thereby reducing the size of the region on the semiconductor wafer allocated for the cleaving of the wafer (referred to as the “cleaving region”). It is known that in order to form straight cleavage lines, it is effective to cleave the wafer (of single crystal material) along crystal orientations.

Cleaving of a semiconductor wafer in general will now be briefly described with reference to FIGS. 9 to 12. Referring to FIG. 9, a semiconductor layer, an insulating film 105, and an electrode 101 are formed on a single crystal wafer 102 in that order. The insulating film 105 has a uniform thickness. Further, the electrode 101 includes narrow portions 104, as shown in FIG. 10, which is an enlarged view of a portion of FIG. 9. A cleaving region 103 is defined to include the narrow portions 104, and cleavage is caused to propagate along this cleaving region 103, i.e., propagate perpendicular to the narrow portions 104. That is, the cleaving region 103 extends along a crystal orientation of the single crystal wafer 102.

FIG. 11 is a diagram illustrating a process of making a cut or slit 112 in the semiconductor wafer with, e.g., a diamond needle 111, etc. to facilitate splitting of the wafer. The cut 112 is formed so as to allow cleavage to propagate across the narrow portions 104, as shown in FIG. 11.

A force is then applied to the surface of the single crystal wafer 102 opposite that having the cut 112, as indicated by the arrow in FIG. 12. This application of force causes cleavage to start at the cut 112 and propagate along a crystal orientation of the single crystal wafer 102, resulting in the formation of semiconductor devices having flat end faces.

Patent Documents 1 to 4 disclose other methods of splitting a semiconductor wafer into individual semiconductor devices. The Patent documents 1 to 4 are Japanese Laid-Open Patent Publication No. 2004-134701, 2007-134447, 2006-203002, and H6-151583.

The cleavage lines are desired to be straight, as described above. It has been found, however, that films formed on the wafer, such as an insulating film, may prevent cleavage from propagating in a straight line along a crystal orientation. Further, a non-straight cleavage line may also result depending on the location on the wafer to which the above cleaving force is applied. Problems associated with non-straight cleavage lines will now be described.

It has been found that when a cleavage line is not straight, the resulting end faces of the individual devices may be uneven and have a step-like configuration. Particularly in the case of semiconductor light emitting devices, degradation of the flatness of the end faces will result in degradation of the light emitting characteristics and the reliability of the devices.

Referring now to the plan view in FIG. 13A of FIG. 13, a cleavage line 121 bends and extends out of the cleaving region 103. FIG. 13B is an elevational view of an end face formed as a result of this cleavage, showing that the end face has a step-like configuration 122 which results from the cleavage line extending out of the cleaving region 103.

FIG. 14 illustrates another cleavage line that is also not straight although it extends along and within the cleaving region. Referring to the plan view in FIG. 14A of FIG. 14, a cleavage line 124 is not straight. FIG. 14B is an elevational view of an end face formed as a result of this cleavage, showing that the end face has a step 122. The semiconductor devices shown in FIGS. 13 and 14 are light emitting devices each having a light emitting region 123 exposed at an end face thereof. These light emitting devices shown in FIGS. 13 and 14 are found to have degraded light emitting characteristics and degraded reliability, since a step or steps are located at or near their light emitting region 123. That is, a problem arises if the cleavage line is not straight, regardless of whether or not it extends out of the cleaving region.

Patent Document 1 discloses a construction that allows for formation of a straight cleavage line. Specifically, the construction disclosed in Patent Document 1 is characterized in that insulating film removed regions 132 in which an insulating film 131 is not formed or from which the insulating film 131 has been removed are disposed along cleavage lines 133 (indicated by broken lines), as shown in FIG. 15. The insulating film removed regions 132 extend across narrow portions of an electrode 134. If cleavage is caused to propagate along and within each insulating film removed region 132, the resulting cleavage line is straight, since there is no insulating film that prevents the propagation.

Incidentally, each individual semiconductor light emitting device separated from a wafer by cleaving is often mounted on a heat dissipating block such that the surface of the device having a semiconductor layer, an insulating film, and an electrode formed thereon is bonded to the block by solder since intense heat is likely to develop over this surface. This structure will be described with reference to FIG. 16. An insulating film 131 and an electrode 134 are formed on a wafer 141 with a semiconductor layer formed therein. Insulating film removed regions 132 in which the insulating film 131 is absent partially extend over the wafer 141. The surface of the wafer 141 having the insulating film removed regions 132 thereon is turned to face downward, and the electrode 134 is bonded to a heat dissipating block 143 by solder 144, as indicated by the arrow in FIG. 16. It has been found, however, that in this mounting process, the surface of the insulating film removed regions 132 (i.e., the surface of the semiconductor layer) may come into contact with the solder 144 or the heat dissipating block 143, causing electrical shorting.

### SUMMARY OF THE INVENTION

The present invention has been made to solve the above problems. It is, therefore, an object to the present invention to provide a method of manufacturing semiconductor devices which is capable of forming straight cleavage lines and also capable of preventing shorting between the semiconductor layer in each semiconductor device and the heat dissipating block on which the device is mounted.

According to one aspect of the present invention, a method of manufacturing semiconductor devices by cleaving a semiconductor wafer along a crystal orientation of the semiconductor wafer includes the steps of forming a semiconductor layer on the semiconductor wafer, forming an insulating film on the semiconductor layer such that the insulating film includes an insulating film thinned region extending parallel to the crystal orientation and being thinner than the other regions of the insulating film, forming an electrode on the insulating film such that the electrode crosses the insulating film thinned region, forming a cut in the insulating film thinned region, the cut serving as a starting point for cleavage, and cleaving the semiconductor wafer such that cleavage starts at the cut andpropagates along the insulating film thinned region.

According to another aspect of the present invention a method of manufacturing semiconductor devices by cleaving a semiconductor wafer along a crystal orientation of the semiconductor wafer, includes the steps of forming a semiconductor layer on the semiconductor wafer, forming an insulating film on the semiconductor layer such that a series of spaced insulating film removed regions in which the insulating film is absent are formed on the semiconductor layer in a direction parallel to the crystal orientation, forming an electrode on the insulating film such that the electrode crosses the direction in which the series of insulating film removed regions are formed, forming a cut in one of the series of insulating film removed regions, the cut serving as a starting point for cleavage, and cleaving the semiconductor wafer such that cleavage starts at the cut andpropagates along the series of insulating film removed regions.

Other and further objects, features and advantages of the invention will appear more fully from the following description.

### BRIEF DESCRIPTION OF THE DRAWINGS

FIG. 1 is a flowchart illustrating a method of manufacturing semiconductor devices according to the first embodiment;

FIG. 2 is an enlarged view of a portion of the semiconductor wafer;

FIG. 3 is a cross-sectional view taken along broken line 3-3 of FIG. 2;

FIG. 4 is a cross-sectional view taken along broken line 4-4 of FIG. 2;

FIG. 5 is a cross-sectional view taken along broken line 5-5 of FIG. 2;

FIG. 6 shows a cleavage lines formed as a result of the cleaving process;

FIG. 7 is an enlarged view of the surface of a semiconductor wafer structure ready to be cleaved in the method of manufacturing semiconductor devices according to the second embodiment;

FIG. 8 is a diagram illustrating a cleaving process of the second embodiment;

FIG. 9 explains the cleaving of a semiconductor wafer according to the related process;

FIG. 10 is an enlarged view of a portion of FIG. 9;

FIG. 11 is a diagram illustrating a process of making a cut or slit in the semiconductor wafer with, e.g., a diamond needle;

FIG. 12 shows an application of the force to the single crystal wafer;

FIG. 13A shows a cleavage line extending out of the cleaving region;

FIG. 13B is an elevational view of an end face formed as a result of the cleavage;

FIG. 14A shows a non-straight cleavage line;

FIG. 14B is an elevational view of an end face formed as a result of the non-straight cleavage;

FIG. 15 explains a problem of the related art; and

FIG. 16 explains a problem of the related art.

### DETAILED DESCRIPTION OF THE PREFERRED EMBODIMENTS

### First Embodiment

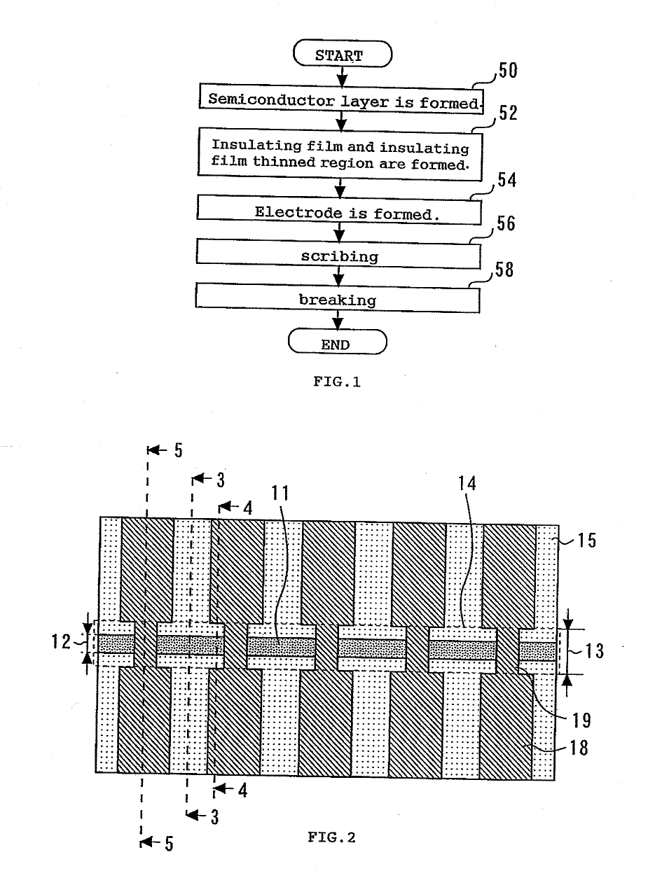

A first embodiment of the present invention will be described with reference to FIGS. 1 to 6. It should be noted that throughout the description of the first embodiment, like numerals represent like materials or like or corresponding components, and these materials or components may be described only once. This also applies to other embodiments of the invention subsequently described.

FIG. 1 is a flowchart illustrating a method of manufacturing semiconductor devices according to the present embodiment. This method will now be described with reference to the flowchart. First, a semiconductor layer is formed on a semiconductor wafer such as a single crystal wafer at step 50.

After the completion of step 50, the method proceeds to step 52 at which an insulating film is formed on the semiconductor layer. The insulating film includes an insulating film thinned region which extends along a crystal orientation of the semiconductor wafer and which is thinner than the other regions of the insulating film. The insulating film thinned region may be formed by wet or dry etching, or alternatively, it may be a separately formed thinner film. This insulating film thinned region will be described later.

After the completion of step 52, the method proceeds to step 54 at which an electrode is formed. Step 54 will be described with reference to FIG. 2, which is an enlarged view of a portion of the semiconductor wafer. At step 54 an electrode 18 is formed to cross the insulating film thinned region 11. The electrode 18 includes narrow portions 19 which are narrower than the other portions of the electrode 18 and which cross the insulating film thinned region 11. These narrow portions 19 are used to recognize the electrode pattern image at a subsequent breaking step (described later). It will be noted that the cleaving region 14 is indicated by broken lines in FIG. 2.

The width of the insulating film thinned region 11 is herein referred to as the “film thinned region width,” and denoted by reference numeral 12. Further, the length of the narrow portions 19 of the electrode 18 in the direction in which the electrode 18 extends is herein referred to as the “narrow portion length,” and denoted by reference numeral 13. According to the present embodiment, the narrow portion length 13 is greater than the film thinned region width 12. That is, each narrow portion 19 of the electrode 18 overlaps the entire width of the insulating film thinned region 11.

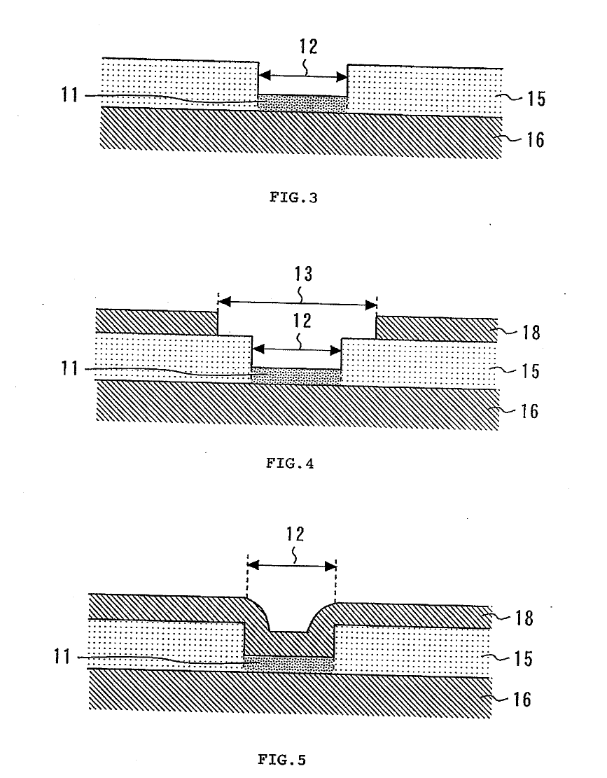

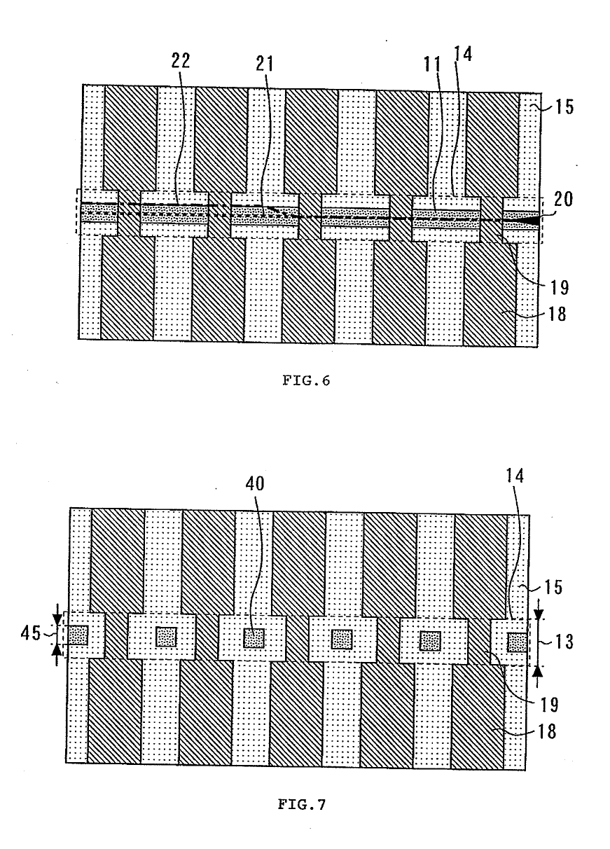

Further, FIG. 3 is a cross-sectional view taken along broken line 3-3 of FIG. 2, FIG. 4 is a cross-sectional view taken along broken line 4-4 of FIG. 2, and FIG. 5 is a cross-sectional view taken along broken line 5-5 of FIG. 2. As shown in FIG. 3, the insulating film 15 on the semiconductor layer 16 is thinned over the insulating film thinned region 11. The narrow portion length 13 is greater than the film thinned region width 12, as shown in FIG. 4. Further, as shown in FIG. 5, each narrow portion 19 of the electrode 18 is formed integrally with the other portions of the electrode 18.

After the completion of step 54, the method proceeds to step 56 at which a cut serving as a starting point for cleavage (i.e., a cut used to nucleate a cleavage crack) is formed in the insulating film thinned region 11. The formation of this cut is accomplished by use of a diamond needle, etc., as described with reference to FIG. 11. The term “scribing” is used to refer to such formation of a cut serving as a starting point for cleavage.

After the completion of step 56, the method proceeds to step 58 at which a force is applied to the surface of the semiconductor wafer opposite that in which the cut is formed. As a result of the application of this force, stress concentration occurs at the cut. This causes cleavage to start at the cut and propagate along and within the insulating film thinned region, so that the semiconductor wafer is eventually split into pieces. Splitting of a semiconductor wafer in this manner is referred to as “breaking.”

This step 58 completes the process flow, producing the semiconductor devices of the present embodiment. In the present embodiment, cleavage is caused to propagate along and within the insulating film thinned region 11 so that the resulting cleavage line is straight. That is, since the insulating film is thinned over the insulating film thinned region 11, the resistance to the propagation of cleavage offered by the insulating film is not significant in this region 11, thus facilitating the cleavage to propagate in a straight line along a crystal orientation.

Typical cleavage lines formed as a result of the cleaving process of the present embodiment will now be described with reference to FIG. 6. At the scribing step described above the cut 20 is formed in the insulating film thinned region 11, and then cleavage is caused to start at the cut 20 and propagate. The construction of the present embodiment makes it highly likely that a straight cleavage line will be formed, as indicated by broken line 21 in FIG. 6. However, even if the cleavage propagation direction deviates from the direction of the length of the insulating film thinned region 11, the cleavage propagation is still confined within the insulating film thinned region 11 since the insulating film is thinned over this region, resulting in the formation of a substantially straight cleavage line, as indicated by dashed line 22 in FIG. 6. That is, the configuration of the insulating film thinned region 11 prevents the cleavage crack from propagating out of the region 11. Thus, a straight or substantially straight cleavage line can be formed by reducing the width 12 of the insulating film thinned region 11. Since the narrow portion length 13 is greater than the film thinned region width 12, a cleavage line can be formed to pass through the narrow portions 19. Further, the width 12 of the insulating film thinned region 11 may be reduced as described above to reduce the size of the cleaving region 14.

Further, the construction of the present embodiment differs from that disclosed in Patent Document 1 in that there is no insulating film removed region on the wafer in which the insulating film is absent. As a result, when an individual semiconductor device is bonded to a heat dissipating block, etc., there is no possibility of electrical shorting between the semiconductor layer of the semiconductor device and the heat dissipating block, etc. Further, solder used to assemble other components cannot possibly cause electrical shorting between the semiconductor device and these components, etc. even if the solder contacts or is attached to the semiconductor device, resulting in an increased manufacturing yield.

Thus, the present invention enables a semiconductor wafer to be cleaved so that the individual semiconductor devices separated by this cleaving have exposed end faces that are flat and uniform. These semiconductor devices may be semiconductor light emitting devices, in which case they have improved light emitting characteristics and reliability. The present invention is also advantageous in that it allows a reduction in the size of the cleaving region on the wafer. Therefore, the present invention is not particularly limited to semiconductor light emitting devices, but may be applied to a wide variety of semiconductor devices formed by cleaving.

### Second Embodiment

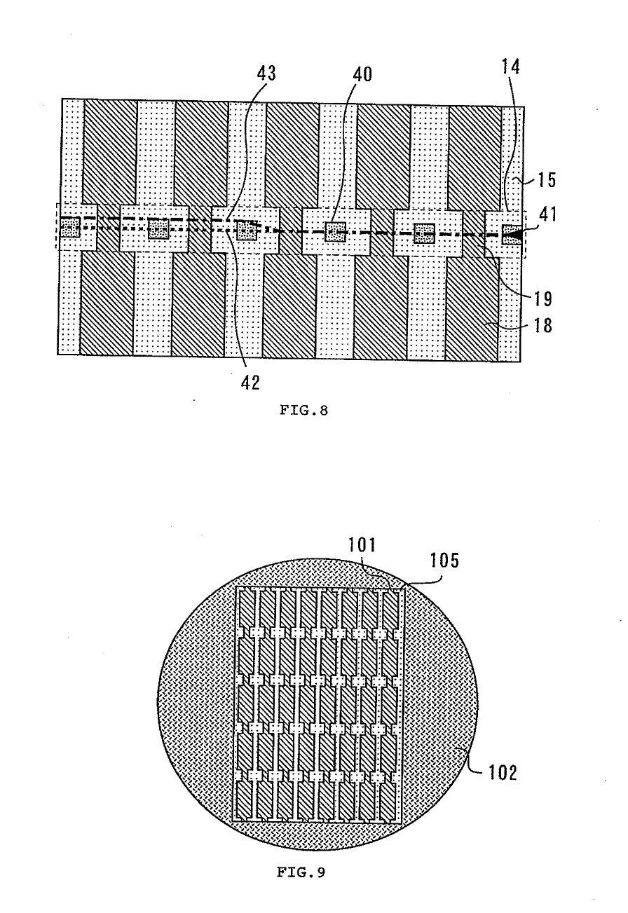

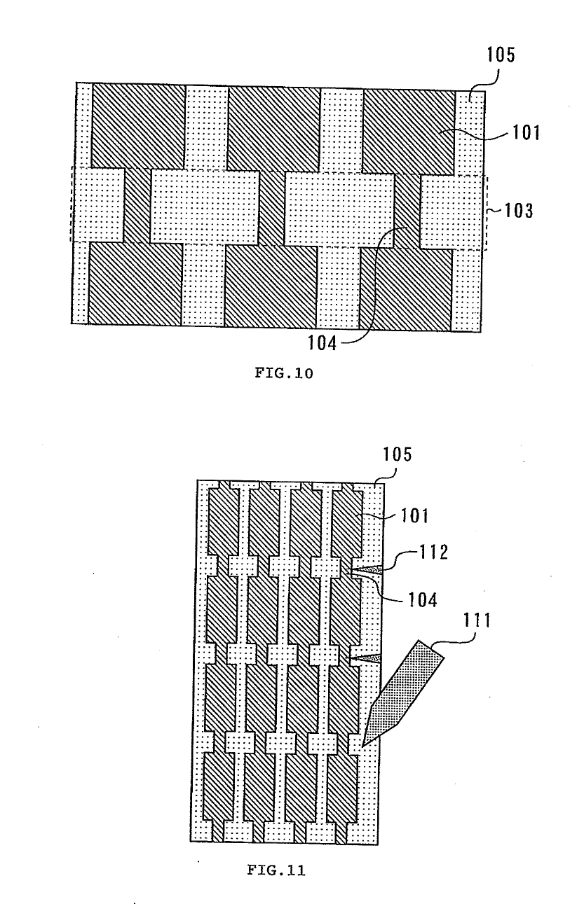

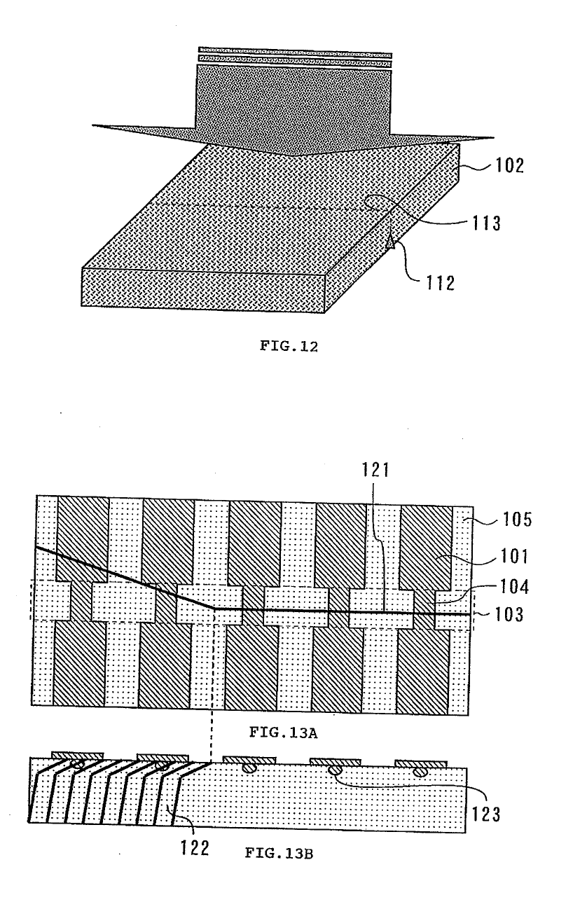

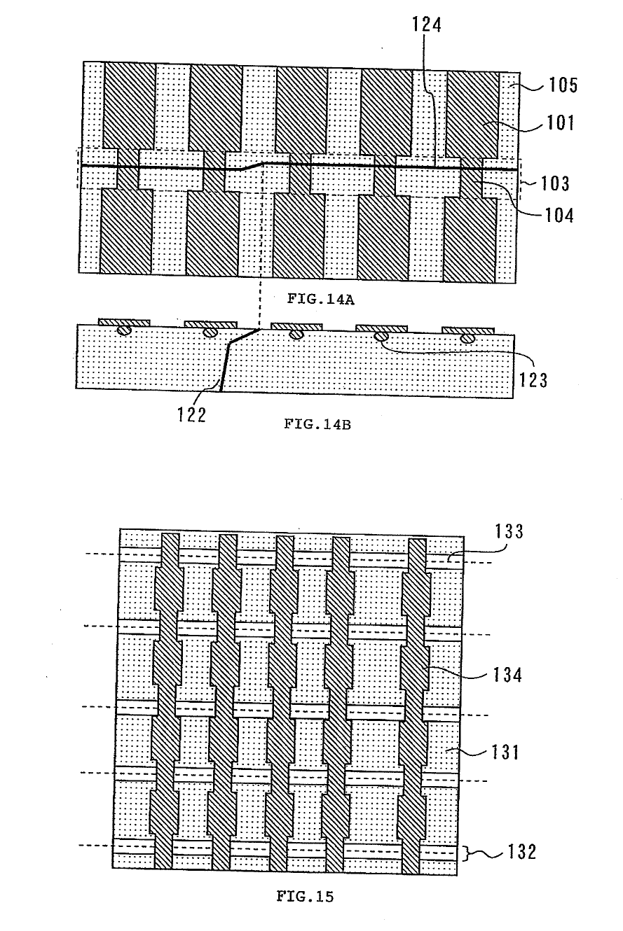

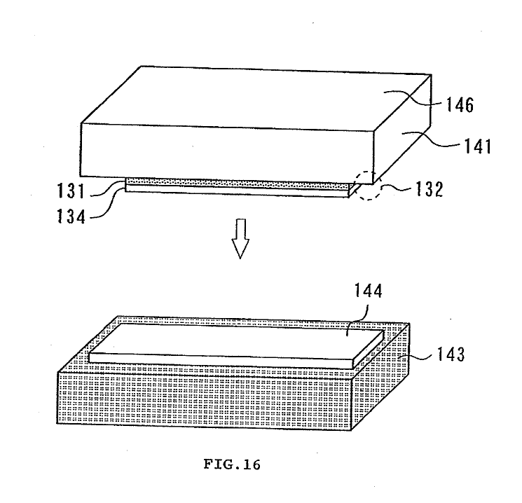

A second embodiment of the present invention relates to a method of manufacturing semiconductor devices by forming a series of spaced small insulating film removed regions on a semiconductor wafer and cleaving the wafer along these insulating film removed regions. This embodiment will be described with reference to FIGS. 7 and 8. It should be noted that the following description of this embodiment will be directed to the differences from the first embodiment.

FIG. 7 is an enlarged view of the surface of a semiconductor wafer structure ready to be cleaved in the method of manufacturing semiconductor devices according to the present embodiment. According to the present embodiment, an insulating film is formed on the semiconductor layer on the semiconductor wafer so that a series of spaced insulating film removed regions 40 on which the insulating film is absent are formed on the semiconductor layer in a direction parallel to a crystal orientation of the wafer. The formation of these insulating film removed regions 40 may be accomplished either by first forming an insulating film over the entire surface of the semiconductor layer and then removing portions of the insulating film, or by forming an insulating film so that it does not cover selected portions of the surface of the semiconductor layer. It should be noted that since the construction of the present embodiment does not include an insulating film thinned region such as that described in connection with the first embodiment, the width 45 of the insulating film removed regions 40 corresponds to the film thinned region width 12 of the first embodiment.

FIG. 8 is a diagram illustrating a cleaving process of the present embodiment. As shown in FIG. 8, a cut 41 is formed in an insulating film removed region 40, and then cleavage is caused to start at the cut 41 and propagate from there. As in the first embodiment, a possible cleavage line formed as a result of this cleavage is a straight cleavage line or a substantially straight cleavage line, as indicated by dashed lines 42 and 43, respectively, in FIG. 8. Thus, the present embodiment, like the first embodiment, is advantageous in that it allows a straight or substantially straight cleavage line to be formed.

In the present embodiment, a series of spaced small insulating film removed regions are formed along the length of the cleaving region. Therefore, when an individual semiconductor device separated from this semiconductor wafer by cleaving is attached to a heat dissipating block or assembledwith other components, there is a low risk of shorting between the semiconductor layer of the device and the heat dissipating block or other components as compared to the case where a single large insulating film removed region continuously extends along the length of the cleaving region.

The method of manufacturing semiconductor devices according to the present embodiment is susceptible of at least alterations which are the same as or corresponding to those that can be made to the method of the first embodiment.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2009-073206, filed on Mar. 25, 2009 including specification, claims, drawings and summary, on which the Convention priority of the present application is based, are incorporated herein by reference in its entirety.

1. A method of manufacturing semiconductor devices by cleaving a semiconductor wafer along a crystal orientation of said semiconductor wafer, comprising:
forming a semiconductor layer on said semiconductor wafer;
forming an insulating film on said semiconductor layer such that said insulating film includes an insulating film thinned region extending parallel to the crystal orientation and that is thinner than other regions of said insulating film;
forming an electrode on said insulating film such that said electrode crosses said insulating film thinned region;
forming a cut in said insulating film thinned region, said cut serving as a starting point for cleaving; and
cleaving said semiconductor wafer such that cleaving starts at said cut and propagates along said insulating film thinned region.

2. The method according to claim 1, wherein:
said electrode has a narrow portion, narrower than other portions of said electrode;
said narrow portion crosses said insulating film thinned region; and
length of said narrow portion in the direction in which said electrode extends is greater than width of said insulating film thinned region.

3. A method of manufacturing semiconductor devices by cleaving a semiconductor wafer along a crystal orientation of said semiconductor wafer, comprising:
forming a semiconductor layer on said semiconductor wafer;
forming an insulating film on said semiconductor layer such that a series of spaced insulating film removed regions in which said insulating film is absent are located on said semiconductor layer in a direction parallel to the crystal orientation;
forming an electrode on said insulating film such that said electrode crosses the direction along which said series of insulating film removed regions are located;
forming a cut in one of said insulating film removed regions, said cut serving as a starting point for cleaving; and
cleaving said semiconductor wafer such that cleaving starts at said cut and propagates along said series of insulating film removed regions.
